(19) United States
(12) Patent Application Publication
(10) Pub. No.: US 2013/0107478 A1
(43) Pub. Date: May 2, 2013

(54) MOUNTING APPARATUS FOR EXPANSION CARDS

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/303,171

(22) Filed: Nov. 23, 2011

(30) Foreign Application Priority Data
Oct. 27, 2011 (CN) 201110331504.8

(51) Int. Cl. H05K 7/10

(52) U.S. Cl. 361/759

(57) ABSTRACT

A mounting apparatus for mounting an expansion card with a block piece includes a housing, a first mounting member, and a second mounting member. The housing includes a side plate and a base fixed to the side plate. The first mounting member is pivotably attached to the base. The second mounting member is pivotably attached to the side plate. The first mounting member is pivotable to press the block piece of the expansion card on the base, the second mounting member is pivotable to abut against the first mounting member toward the block piece.

### BACKGROUND

1. Technical Field

The present disclosure relates to an apparatus for mounting expansion cards.

2. Description of Related Art

Computer systems require expansion cards to expand functions. An expansion card usually includes a main body electrically connectable with a motherboard in a computer system, and a generally L-shaped block plate installable on a rear plate of the computer system. The block plate is usually installed on the rear plate by screws, which is inconvenient.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a mounting apparatus in accordance with an exemplary embodiment together with expansion cards.

FIG. 2 is an enlarged view of an encircled portion II of FIG. 1.

FIG. 3 and FIG. 4 are partial, enlarged, assembled views of FIG. 1, but showing different states of use.

FIG. 5 is a cross-sectional view of FIG. 4, taken along the line of V-V.

### DETAILED DESCRIPTION

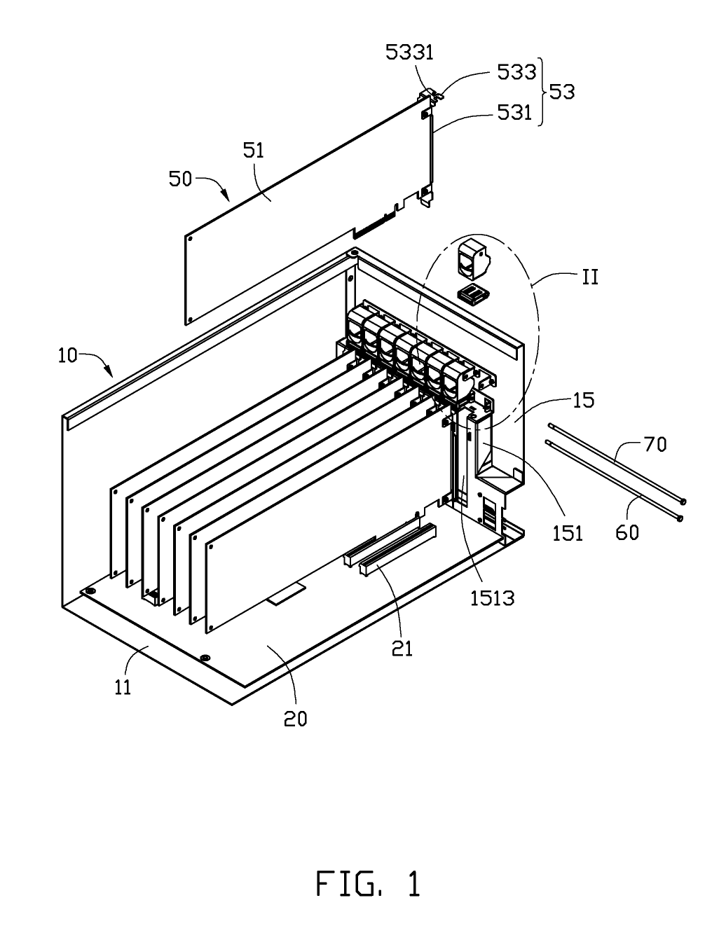

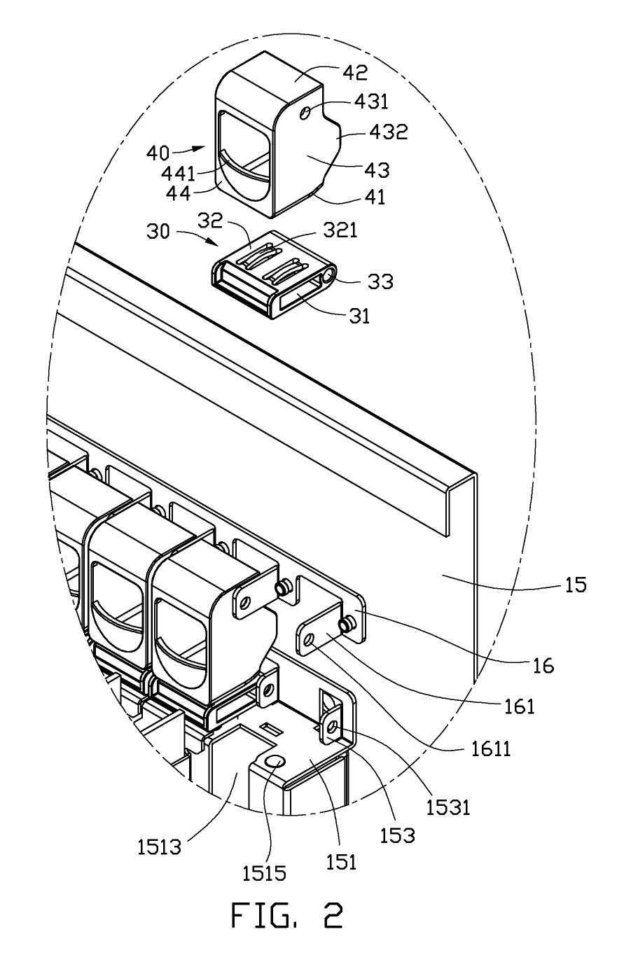

Referring to FIG. 1 and FIG. 2, shows an embodiment of a mounting apparatus for mounting a plurality of expansion cards 50 to a housing 10 of an electronic device. The mounting apparatus includes a plurality of first mounting members 30 and a plurality of second mounting members 40.

Each expansion card 50 includes a circuit board 51 and an L-shaped block piece 53 fixed to one end of the circuit board 51. The block piece 53 includes a block portion 531 and a bent portion 533 extending from a top end of the block portion 531. A cutout 5331 is defined in the bent portion 533.

The housing 10 includes a bottom plate 11 and a side plate 15 extending perpendicularly up from the bottom plate 11. A motherboard 20 is set on the bottom plate 11. A plurality of expansion slots 21 is formed on the motherboard 20. A base 151 is formed from the side plate 15 adjacent to the bottom plate 11. A plurality of parallel L-shaped slots 1513 is defined in the base 151, corresponding to the expansion slots 21. A protrusion 1515 protrudes on the base 151 adjacent to each of the slots 1513. A pair of parallel connecting pieces 153 extends from the base 151 above each corresponding protrusion 1515 corresponding to each slot 1513. A connecting hole 1531 is defined in each connecting piece 153. A mounting piece 16 is fixed to the side plate 15 above the connecting pieces 153. A pair of parallel flanges 161 extends from the mounting piece 16 corresponding to each pair of connecting pieces 153. A pivot hole 1611 is defined in each mounting piece 16.

Each first mounting member 30 is substantially box shaped, and includes a bottom wall 31 and a top wall 32 parallel to the bottom wall 31. A through hole 33 is defined in a first side of the first mounting member 30 and between the bottom wall 31 and the top wall 32. Two resilient raised portions 321 are formed on the top wall 32.

Each second mounting member 40 is substantially frame shaped, and includes a bottom plate 41, a top plate 42 parallel to the bottom plate 41. Two side plates 43 are connected between corresponding sides of the bottom plate 41 and the top plate 42, and a front plate 44 are connected between front sides of the bottom plate 41 and the top plate 42. Two through holes 431 are respectively defined in the side plates 43 adjacent to the top plate 42. The front plate 44 defines an opening to form an operation portion 441 below the opening. A limiting portion 432 extends from each side plate 43 away from the front plate 44.

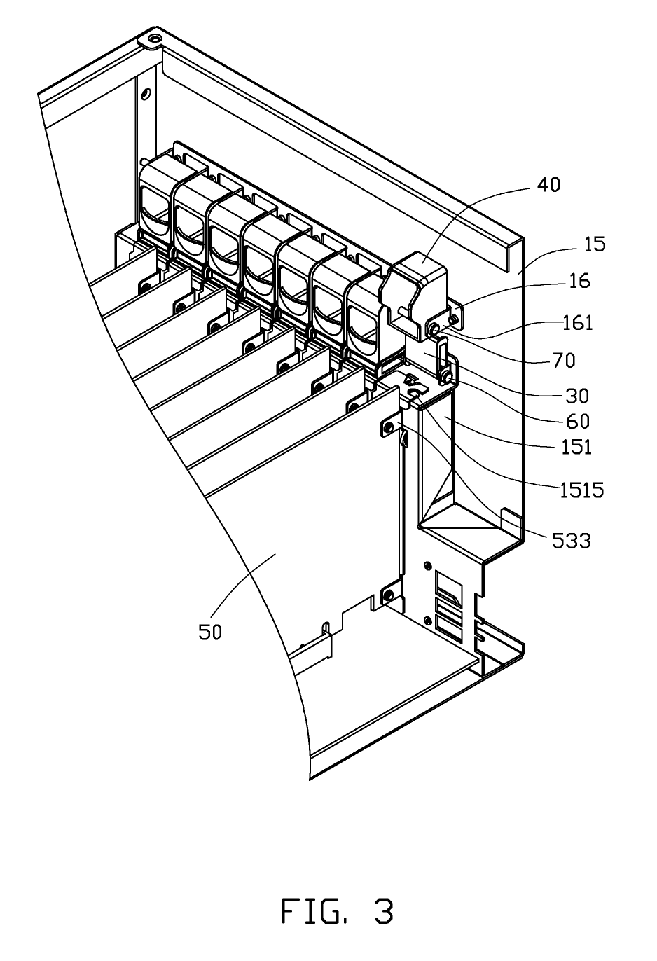

Referring to FIG. 3, in assembly, a first shaft 60 extends through the connecting holes 1531 and the through holes 33 to pivotably attach the first mounting members 30 to the base 151. A second shaft 70 extends through the pivot holes 1611 and the through holes 431 to pivotably attach the second mounting members 40 to the side plate 15.

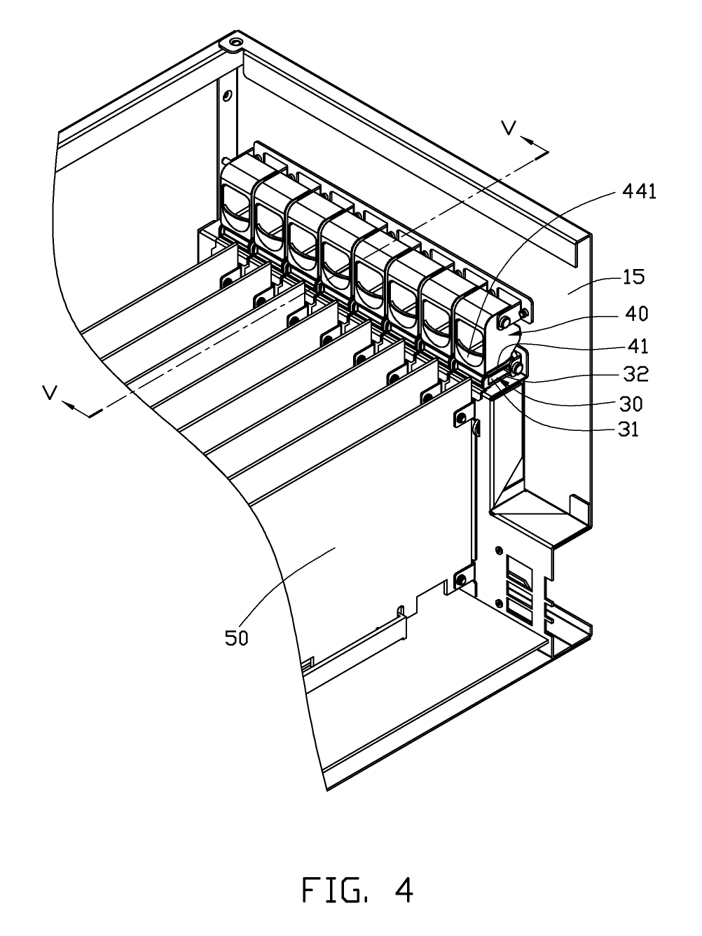

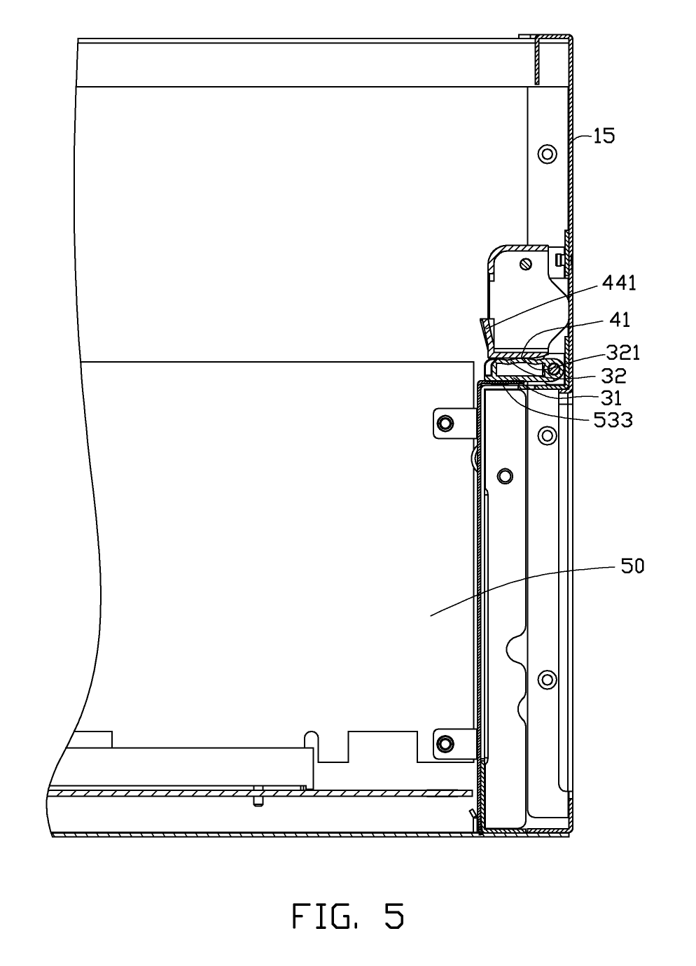

Referring to FIG. 4 and FIG. 5, in mounting each expansion card 50, the expansion card 50 is inserted into a corresponding expansion slot 21. The block portion 531 of the block piece 53 shields a corresponding slot 1513. The bent portion 533 is supported on the base 151. A corresponding protrusion 1515 engages in the cutout 5331. A corresponding first mounting member 30 is rotated toward the expansion card 50 until the bottom wall 31 abuts against the bent portion 533. A corresponding second mounting member 40 is rotated toward the expansion card 50 until the limiting portions 432 abut against the side plate 15. The bottom plate 41 abuts against the top wall 32 and the raised portions 321. Therefore, the bottom wall 31 presses the bent portion 533 on the base 151 to mount the expansion card 50 in the housing 10.

In releasing the expansion card 50, the operation portion 441 is operated to rotate the second mounting member 40 toward the side plate 15 to release the second mounting member 40 from the first mounting member 30. The first mounting member 30 is then rotated toward the side plate 15 to release the bent portion 533 from the base 151. Therefore, the expansion card 50 can be detached from the housing 10.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A mounting apparatus for mounting an expansion card with a block piece, comprising:
a housing comprising a side plate and a base fixed to the side plate;
a first mounting member pivotably attached to the base; and
a second mounting member pivotably attached to the side plate above the first mounting member, wherein the first mounting member is pivotable to press the block piece of the expansion card on the base, the second mounting member is pivotable to abut against the first mounting member toward the block piece.

2. The mounting apparatus of claim 1, wherein the block piece comprises a bent portion supported on the base, the bent portion defines a cutout, a protrusion protrudes on the base and engages in the cutout.

3. The mounting apparatus of claim 1, wherein the base defines a slot, a pair of parallel connecting pieces extend inward from the base above the slot, each of the connecting pieces defines a connecting hole, a through hole is defined in a side of the first mounting member, a first shaft extends through the connecting holes and the through hole of the first mounting member to pivotably attach the first mounting member to the base.

4. The mounting apparatus of claim 3, wherein a pair of parallel flanges extend from the side plate above the pair of the connecting pieces, a pivot hole is defined in each of the flanges, the second mounting member defines a through hole, a second shaft extends through the through hole of the second mounting member and the pivot holes to pivotably attach the second mounting member to the side plate.

5. The mounting apparatus of claim 1, wherein the first mounting member comprises a bottom wall and a top wall parallel to the bottom wall, the second mounting member comprises a bottom plate and a top plate parallel to the bottom plate, the bottom wall abuts against the block piece, the bottom plate abuts against the top wall.

6. The mounting apparatus of claim 5, wherein two resilient raised portions are formed on the top wall of the first mounting member, to abut against the bottom plate of the second mounting member.

7. The mounting apparatus of claim 5, wherein the second mounting member comprises two side plates and a front plate connected between the side plates, a limiting portion extends from each of the side plates of the second mounting member away from the front plate, to abut against the side plate of the housing.

8. The mounting apparatus of claim 7, wherein an operation portion is formed on the front plate, the operation portion is operable to rotate the second mounting member.

9. An electronic device comprising:
a housing comprising a side plate and a base fixed to the side plate;
an expansion card comprising a circuit board and a block piece fixed to one end of the circuit board;
a first mounting member pivotably attached to the base; and
a second mounting member pivotably attached to the side plate, wherein the first mounting member is pivotable to press the block piece of the expansion card on the base, the second mounting member is pivotable to abut against the first mounting member toward the block piece.

10. The electronic device of claim 9, wherein the block piece comprises a bent portion supported on the base, the bent portion defines a cutout, a protrusion protrudes on the base and engages in the cutout.

11. The electronic device of claim 9, wherein the base defines a slot, a pair of parallel connecting pieces extend inward from the base above the slot, each of the connecting pieces defines a connecting hole, a through hole is defined in a side of the first mounting member, a first shaft extends through the connecting holes and the through hole of the first mounting member to pivotably attach the first mounting member to the base.

12. The electronic device of claim 11, wherein a pair of parallel flanges extend from the side plate above the connecting pieces, a pivot hole is defined in each of the flanges, the second mounting member defines a through hole, a second shaft extends through the through hole of the second mounting member and the pivot holes to pivotably attach the second mounting member to the side plate.

13. The electronic device of claim 9, wherein the first mounting member comprises a bottom wall and a top wall parallel to the bottom wall, the second mounting member comprises a bottom plate and a top plate parallel to the bottom plate, the bottom wall abuts against the block piece, the bottom plate abuts against the top wall.

14. The electronic device of claim 13, wherein two resilient raised portions are formed on the top wall of the first mounting member, to abut against the bottom plate of the second mounting member.

15. The electronic device of claim 13, wherein the second mounting member comprises two side plates and a front plate connected between the side plates, a limiting portion extends from each of the side plates of the second mounting member away from the front plate, to abut against the side plate of the housing.

16. The electronic device of claim 15, wherein an operation portion is formed on the front plate, the operation portion is operable to rotate the second mounting member.
